(19) United States
(12) Patent Application Publication
(10) Pub. No.: US 2026/0140211 A1
(43) Pub. Date: May 21, 2026

(54) Interpolated Imaging

(71) Applicant: Siemens Healthineers AG, Forchheim (DE)

(72) Inventors: Christian Meixner, Erlangen (DE); Marcel Dominik Nickel, Herzogenaurach (DE); Mario Zeller, Erlangen (DE)

(73) Assignee: Siemens Healthineers AG, Forchheim (DE)

(21) Appl. No.: 19/388,015

(22) Filed: Nov. 13, 2025

(30) Foreign Application Priority Data
Nov. 15, 2024 (DE) 10 2024 210 998.3

(51) Int. Cl. G01R 33/48; G01R 33/56

(52) U.S. Cl. CPC G01R 33/4818; G01R 33/5608

(57) ABSTRACT

A method for the artifact-reduced generation of formatted interpolated image data, including capturing image data from an image capture area, generating supplemented image data in an image boundary area by supplementing the image data with zero values; generating supplemented k-space data by transforming the supplemented image data into the k-space; generating interpolated k-space data by interpolating the supplemented k-space data, generating interpolated image data using an image reconstruction based on the interpolated k-space data, and generating formatted interpolated image data by removing boundary areas of the interpolated image data.

### TECHNICAL FIELD

The disclosure relates to a method for generating formatted interpolated image data. The disclosure also relates to an image data generation device. The disclosure additionally relates to a magnetic resonance imaging system.

### BACKGROUND

When image data is processed by means of interpolation in the Fourier domain (in magnetic resonance imaging, the Fourier domain is usually called the k-space) with respect to its resolution, image artifacts may occur if the object to be depicted does not fit completely within the image area. Such a scenario is illustrated in FIG. 1. First and foremost, image data should generally be understood as information displayed in image form that relates to measurement data. The image data was thus generated by an image capture unit from an image capture area by means of a physical measurement. The term “image capture unit” should comprise, in particular, image capture units operating with optical methods, but also imaging systems that operate with active excitation of an area to be captured by means of electromagnetic waves, in particular, high-frequency signals or X-ray radiation, which was emitted by the image capture unit itself. A particularly important type of imaging, especially in medicine, comprises magnetic resonance imaging or magnetic resonance measurement.

Imaging systems that are based on a magnetic resonance measurement method, in particular, nuclear spin, so-called magnetic resonance scanners, also referred to as magnetic resonance imaging systems, have successfully established and proven themselves through a wide array of applications. This type of image acquisition usually involves a static basic magnetic field B0, which is used for initial alignment and homogenization of magnetic dipoles to be examined, being superimposed with a rapidly switched magnetic field, the so-called gradient field, for spatial resolution of the imaging signal. To determine the material properties of an examination object to be captured, the dephasing or relaxation time after a deflection of the magnetization from the initial alignment is determined, so that various relaxation mechanisms or relaxation times that are typical of the material can be identified. The deflection normally takes the form of a number of HF pulses (HF=high frequency), also referred to as excitation pulses, and the spatial resolution is based on a manipulation of the deflected magnetization that is fixed in time with the aid of the gradient field in a so-called measurement sequence or actuation sequence, which determines a precise chronological sequence of HF pulses, the change in the gradient field (due to the transmission of a switching sequence of gradient pulses) and the recording of measured values.

Typically, an assignment is carried out between measured magnetization—from which the above-mentioned material properties can be derived—and a spatial coordinate of the measured magnetization in the spatial domain in which the examination object is arranged, with the aid of an intermediate step. In this intermediate step, recorded magnetic resonance raw data, also referred to as k-space data, is arranged at read-out points in the so-called “k-space”, the coordinates of the k-space being coded as a function of the gradient field. The magnitude of the magnetization (in particular the transverse magnetization in a plane transverse to the above-described basic magnetic field) at a specific location on the examination object can be determined from the data of the read-out point with the aid of a Fourier transform, which uses a signal strength (magnitude of the magnetization), which is assigned to a specific frequency (the spatial frequency) or phase position, to calculate a signal strength of the signal in the spatial domain. The presentation of signal values in the spatial domain as image data is frequently also identified by the term image space or image data space, in contrast to the k-space, in which signals are presented as a function of frequencies and phases. The k-space is sometimes also called the frequency space or Fourier space. This latter term refers to the fact that k-space data can be obtained by means of a Fourier transform of image data.

However, it is common to perform only a partial sampling of the k-space to save time. The reduced sampling of the k-space, however, leads to a reduction in the image information reconstructed based on the sampled k-space data, in particular, to a reduction in the image resolution. In order to compensate for this information loss, methods exist that compensate for the undersampling. Such interpolation methods can be associated with an augmentation of the k-space data, as well as aiming to directly increase the resolution in the image data space. Otherwise, it is necessary to increase the resolution through interpolation, also for image data that is not undersampled, or even for oversampled image data.

For an image interpolation in the frequency space or k-space, the image to be interpolated is first transformed into the k-space and is then interpolated by means of zero filling, or with the aid of artificial data using a method based on artificial intelligence (abbreviated to “AI”), for example, a deep resolve sharp method. For example, the number of image points of a 2D capture measuring 128*128 pixels is doubled to 256*256 pixels, and the distance between pixels in a field of view of 128*128 mm 2 is thereby halved from 1 mm to 0.5 mm. This method is frequently used in MR imaging. However, this can result in aliasing artifacts after the image interpolation, as shown in FIG. 1, if the object to be examined is larger than the field of view (abbreviated to “FOV”).

Deep Resolve Sharp (abbreviated to “DRS”) is a method for interpolating MR images using a neural super-resolution network, with which the resolution of image data can be increased. Such a method is described in Yulun Zhang et al. “Residual Dense Network for Image Super-Resolution.” Proceedings of the IEEE conference on computer vision and pattern recognition, 2018.

“Deep Resolve” is an advanced medical imaging technology that combines deep learning and artificial intelligence technology to improve the process of image reconstruction through magnetic resonance tomography (MRT) and, in particular, to increase the resolution and sharpness of magnetic resonance images. It comprises multiple components, including Deep Resolve Sharp and Deep Resolve Boost.

To avoid aliasing of large objects in MR imaging, the k-space is generally oversampled during the image capture. In the frequency encoding direction, this can usually be done without any additional time outlay. After the actual image reconstruction of the k-space into the image data space or the spatial domain (e.g., with Fourier transform, GRAPPA (“GeneRalized Autocalibrating Partial Parallel Acquisition”), or SENSE (“Sensitivity Encoding”), the oversampled area is cut away so that only the desired field of view remains. If image interpolation is then carried out, the problem mentioned at the outset can occur, namely that aliasing artifacts can occur since the information from the oversampled image area is now missing.

To date, this problem has been solved by interpolating the k-space data (e.g., with zero filling) before the actual image reconstruction. However, this causes the reconstruction to take longer, especially if relatively advanced reconstruction technologies are used, e.g., AI-assisted technologies (AI=Artificial Intelligence). In the case of Siemens Healthineers MR (“MR”=“Magnetic resonance imaging”), the method known as “Deep Resolve Boost” (abbreviated to “DRB”) is used.

FIG. 2 is a schematic representation of the reconstruction chain for a conventional reconstruction and thus a customary solution for the interpolation of image data.

FIG. 3 shows the reconstruction chain in which an advanced reconstruction technology is used (e.g., DRB). In the latter reconstruction chain, the duration of the reconstruction is reduced by means of the prior cutting away of the image boundary area caused by an oversampling, which results in a smaller volume of data being generated for processing; however, the reduction in the data volume can result in the above-described aliasing artifacts, for which there has to date been no solution that can eliminate or reduce these artifacts.

### SUMMARY

It is, therefore, an object in magnetic resonance imaging to avoid or at least to reduce artifacts and, in particular, aliasing artifacts when increasing the resolution of magnetic resonance image data by means of interpolation, and/or to reduce the time outlay in comparison with a conventional procedure that does not involve data reduction.

This object is realized by a method for generating formatted interpolated image data as claimed in claim 1, an image data generation device as claimed in claim 11, and a magnetic resonance imaging system as claimed in claim 13.

In the method according to the disclosure for the preferably artifact-reduced generation of formatted interpolated image data, image data is captured from an image capture area. The image data has a predetermined image format that depicts the image capture area. As already briefly explained at the start, the “capture of image data” should be understood to mean a measurement based on which image information relating to a local or spatial distribution of the measured values or values determined based on the measured values is generated. A particularly preferable type of image capture or imaging is magnetic resonance imaging. However, the method according to the disclosure is not limited to magnetic resonance imaging. The method, according to the disclosure, is intended generally for increasing the resolution of image data that is captured by means of measurements.

After the image capture, which preferably, especially for the particularly important variant of magnetic resonance imaging, comprises an image reconstruction, supplemented image data, preferably obtained by supplementing the image data with zero values, is generated in a predetermined image boundary area. The predetermined image boundary area lies outside the depicted predetermined image format and borders on the predetermined image format. “Outside the predetermined image format” is intended to mean that the predetermined image boundary area lies outside the bounds of the predetermined image format.

Preferably, the image boundary area selected for the supplementation is that in which an object to be depicted is “cut off” by the image boundary, in other words, is only partially depicted, where the object extends to the image boundary. Put clearly, a “dummy” image area is thus added at a selected image boundary that then forms the predetermined image boundary area. This image boundary area is created in such a way that no aliasing artifacts occur during a transformation or interpolation. This added image area preferably comprises a single column or row, or a layer one voxel thick, for this purpose. This measure makes it possible to prevent aliasing artifacts that are caused by objects appearing in the image boundary area. Furthermore, supplemented k-space data is generated by transforming the supplemented image data into the k-space. Such a transformation is preferably carried out by means of a Fourier transform. “k-space” should be understood to mean, in particular, the k-space used in magnetic resonance imaging. Furthermore, this should also be understood as a Fourier space into which image data is transformed from the spatial domain or the image data space by means of a Fourier transform. The latter applies, in particular, to image data that was not generated by magnetic resonance imaging.

Interpolated k-space data is then generated by interpolating the supplemented k-space data, by means of which non-measured k-space data is generated based on the supplemented k-space data. In such an interpolation, additional k-space data is preferably supplemented between existing k-space data as intermediate values or intermediate data, for example, based on the existing k-space data. A particularly preferable method comprises “zero filling”, in which the k-space is simply filled with zero values.

Zero filling is routinely used to expand the image matrix size in the phase-encoded direction. In 2D imaging, this enlargement of the matrix size takes place “within the plane” (e.g., from 256 to 512 pixels). The gains occur with the first doubling of the matrix size. No further benefits are realized after this. Although zero filling does not add any information to the input raw data, it can nonetheless improve the apparent spatial resolution of the image due to reduced partial volume artifacts. The zero filling serves as a method for interpolating the signals of neighboring voxels and gives the image a smoother and less “pixelated” appearance.

Interpolated image data is then generated by means of an image reconstruction based on the interpolated k-space data. The image reconstruction is preferably carried out by means of a Fourier transform of the interpolated k-space data into the image data space. As a consequence of the supplementation of the image data with an image boundary area and as a consequence of the transformations in connection with the interpolation, the interpolated image data has image boundary areas that lie outside the predetermined image format.

Finally, formatted interpolated image data is generated by removing the image boundary areas, which lie outside the predetermined image format, in the interpolated image data. Here, preferably, opposing image boundary areas in the interpolated image data that correspond to the image boundary area that was already generated in the step of generating supplemented image data are eliminated. Here, the removed image boundary areas are aligned analogously to the image boundary area added during the supplementation step in the image space or comprise this boundary area with respect to its extent and arrangement. The removal of the image boundary areas restores the original format of the image data used as input data. Put another way, the supplementation of the image data in the image boundary area before the interpolation is reversed after the interpolation, so that the original image format is preserved. Aliasing artifacts are advantageously prevented, in particular, where objects or important image areas border on the boundary of the image capture area or extend beyond it.

The image data generation device according to the disclosure has an image capture unit for receiving and/or generating image data from an image capture area with a predetermined image format that depicts the image capture area.

Another element of the image data generation device according to the disclosure is a supplementation unit for generating supplemented image data by adding predetermined image data in a predetermined image boundary area that lies outside the predetermined image format and borders on the predetermined image format. As already explained, the image boundary area is selected such that an image boundary can thereby be supplemented or expanded where an object borders on the image boundary, for example, because it is not fully depicted.

The image data generation device according to the disclosure also comprises a transformation unit for generating supplemented k-space data by transforming the supplemented image data into the k-space or Fourier space. A Fourier transform is preferably used for this.

Another element of the image data generation device according to the disclosure is

an interpolation unit for generating interpolated k-space data by interpolating the supplemented k-space data, by means of which non-measured k-space data is generated based on the supplemented k-space data.

The image data generation device according to the disclosure also comprises an image generation unit for generating interpolated image data by means of an image reconstruction based on the interpolated k-space data, the interpolated image data comprising image boundary areas that lie outside the predetermined image format.

The image reconstruction preferably comprises a Fourier transform, which preferably comprises an inverse operation to the type of transformation used for the transformation of image data into the k-space. A “Fourier transform” can also mean the corresponding inverse transformation, which, linked with the transformation assigned to it, generates the identity. Furthermore, the image data generation device according to the disclosure comprises a formatting unit for generating formatted interpolated image data by removing the image boundary areas in the interpolated image data that lie outside the predetermined image format. With respect to their arrangement, the image boundary areas correspond to the image boundary area that was generated during the generation of the supplemented image data. The image boundary areas preferably comprise opposing image boundary areas that are generated as a result of the transformation into the k-space or Fourier space and the back-transformation into the image space. In this respect, the image boundary areas are arranged and aligned analogously to the predetermined image boundary area that was added during the supplementation step in the image space. In the supplementation step, image boundary areas can also be added in a plurality of dimensions, and image boundary areas can be removed or cut away accordingly in a plurality of dimensions in the formatting step.

The removal of image boundary areas should thus preferably comprise the removal of opposing boundary areas. The image data generation device according to the disclosure shares the advantages of the method according to the disclosure for the preferably artifact-reduced generation of formatted interpolated image data.

If image data that comprises magnetic resonance image data is generated and processed by the image data generation device, the image capture unit thus comprises:
an input interface for receiving k-space data from an examination area of an examination object,
a transformation unit for transforming the received k-space data into the image space, image data being generated,
a reduction unit for generating reduced image data by removing image boundary areas of the image data that lie outside the predetermined image format and border on the predetermined image format,
a back-transformation unit for back-transforming the reduced image data into the k-space, reduced k-space data being generated,
a reconstruction unit for reconstructing magnetic resonance image data based on the reduced k-space data.

Here, the transformation unit preferably comprises a reconstruction function, which preferably differs from the reconstruction function of the reconstruction unit. Preferably, the transformation unit performs the transformation using an algorithm that is relatively simple to implement in mathematical terms, particularly preferably a Fourier transform. By contrast, the algorithm used by the reconstruction unit, preferably a DRS algorithm, is preferably aimed at a particular quality of the image generation and benefits, in particular, from the data reduction by the reduction unit, especially since the improved image quality is usually achieved through increased mathematical and/or operational outlay, which can be reduced or even minimized by the preceding data reduction.

In this preferred aspect of the image data generation device according to the disclosure, an image reconstruction of magnetic resonance image data thus takes place, the volume of image data first being reduced in the image space by means of cutting away one or more boundary areas, reduced k-space data being generated by means of back-transformation of the reduced image data, and the k-space data forming the basis of the image reconstruction thus being reduced, to simplify and/or accelerate subsequent reconstruction processes.

Preferably, due to the reduction of the volume of input data, an existing standard algorithm, preferably based on the principle of super resolution, can be used to increase the image resolution, in particular, a DRS algorithm, with a significant time saving, with the image quality nonetheless being preserved, since compensatory formatting can be carried out in the image data space and, if appropriate, in the k-space after the application of the super resolution algorithm if necessary, with which artifacts resulting from the interpolation can be compensated for. In particular, the reconstruction time can be made independent of the degree of oversampling, as the image data to be interpolated can be limited to a predetermined format by means of the described reduction step, regardless of the degree of oversampling.

The magnetic resonance imaging system according to the disclosure has a scanner unit, a central control device for actuating the scanner unit, and an image data generation device according to the disclosure for processing k-space data of the scanner unit. The magnetic resonance imaging system according to the disclosure shares the advantages of the method according to the disclosure for the generation of formatted interpolated image data.

The majority of the above-mentioned components of the image data generation device according to the disclosure may be implemented in full or in part in the form of software modules in a processor of a corresponding computer system, for example, of a control device of a magnetic resonance imaging system or a computer, used to control such a system. A largely software-based implementation has the advantage that previously used computer systems may also be easily retrofitted with a software update, to work in the manner according to the disclosure. In this respect, the object is also achieved by a corresponding computer program product with a computer program, which may be loaded directly into a computer system, with program sections, for carrying out the steps of the method according to the disclosure for the generation of formatted interpolated image data, if the program is executed in the computer system. Such a computer program product may comprise, as necessary, in addition to the computer program, additional parts such as documentation and/or additional components, as well as hardware components, such as dongles, etc., for using the software.

For transport to the computer system or to the control device and/or for storing on or in the computer system or the control device a computer-readable medium, for example a memory stick, a hard disc or other transportable or integral data carrier may be used, on which the program sections of the computer program readable and executable by a computer system are stored. To this end, the computer system may, for example, have one or more cooperating microprocessors or similar.

The dependent claims and the following description, respectively, contain particularly advantageous aspects and developments of the disclosure. In particular, the claims of one claim category may also be developed analogously to the dependent claims of another claim category. Furthermore, in the context of the disclosure, the various features of different exemplary aspects and claims may also be combined into new exemplary aspects.

Preferably, the generation of formatted interpolated image data should preferably comprise the removal of opposing image boundary areas. This is because, owing to the transformation of the supplemented image data into the k-space and a subsequent back-transformation of the interpolated k-space data into the image space, the image area is “expanded” by an additional area opposing the supplemented image boundary area that is added during the generation of the supplemented image data.

In an aspect of the method according to the disclosure for the artifact-reduced generation of formatted interpolated image data, the generation of supplemented image data is carried out by means of one of the following procedures:
supplementing the predetermined image boundary area with constant values,
supplementing the predetermined image boundary area with a boundary value,
supplementing the predetermined image boundary area with zero values,
supplementing the predetermined image boundary area with image data based on a reflection from an opposing image boundary area or image boundary.

Here, a boundary value should be understood to mean a pixel value or voxel value, in particular, a gray value, present in the boundary area.

A zero value should be understood to mean a constant value that corresponds to an intensity with the value “zero”. Such an intensity is achieved if nothing is present at the location in question or negligible entities are present, which are, for example, shown in black.

A reflection of the image boundary area should be understood to mean that the opposing image boundary area is mirrored on the other side. This is intended to compensate for aliasing on the opposing side.

In one variant of the method according to the disclosure for the artifact-reduced generation of formatted interpolated image data, the image data comprises magnetic resonance image data, or the image data is obtained based on the magnetic resonance image data, and the step of generating image data from an image capture area comprises the following steps:
receiving k-space data from an examination area of an examination object,
reconstructing magnetic resonance image data based on the reduced k-space data.

In this variant, magnetic resonance image data thus forms the basis of the method according to the disclosure as image data. Here, the reconstruction of the image data or the magnetic resonance image data can be carried out using a conventional reconstruction method, for example, GRAPPA, SENSE, or a simple Fourier transform. However, the reconstruction can also include advanced reconstruction methods such as DRB.

In order to speed up the entire method, opposing image boundary areas of the magnetic resonance image data that lie outside the predetermined image format and border on the predetermined image format are then preferably removed to obtain the image data. Reducing the extent of the image surface reduces the data volume of the image data, which speeds up the subsequent image processing. This variant is particularly preferable for the use of conventional reconstruction methods, such as GRAPPA, SENSE, or a simple Fourier transform, and helps speed up subsequent process steps.

If an advanced reconstruction method is used, preferably an AI-based reconstruction method, in particular, DRB, the step of generating image data from an image capture area preferably comprises the following steps:
generating image data by transforming the received k-space data into the image space,
generating reduced image data by removing image boundary areas of the image data that lie outside the predetermined image format and border on the predetermined image format,
generating reduced k-space data by back-transforming the reduced image data into the k-space,
reconstructing the magnetic resonance image data based on the reduced k-space data.

In this particularly advantageous variant, data is already eliminated in the image space before the actual advanced image reconstruction to simplify and/or accelerate a subsequent reconstruction. Particularly preferably, but not restricted thereto, the received k-space data comprises oversampled k-space data. The cutting away of opposing image boundary areas enables the reduction of the data base used as the basis for the actual reconstruction of magnetic resonance image data. In this case, image boundary areas that were caused by the oversampling are cut away in the image space.

As already mentioned in connection with the corresponding device, due to the reduction of the volume of input data, an existing standard algorithm based on the principle of super resolution can be used to increase the image resolution, in particular, a DRS algorithm or DRB algorithm, with a significant time saving, with the image quality nonetheless being preserved, since compensatory formatting can be carried out in the image data space and in the k-space after the application of the super resolution algorithm if necessary, with which artifacts resulting from the interpolation can be compensated for. In particular, the reconstruction time can be made independent of the degree of oversampling, as the image data to be interpolated can be limited to a predetermined format by means of the described reduction step, regardless of the degree of oversampling.

Generally speaking, it can be stated that the method according to the disclosure can be used in particular, but not exclusively, for all types of magnetic resonance image reconstruction methods in which interpolation is carried out after the actual image reconstruction.

Alternatively, in one variant of the method according to the disclosure, the image data comprises image data from an optional image capture unit, preferably a still camera or photographic camera. The method, according to the disclosure, can advantageously be used not just for low artifact, accelerated magnetic resonance imaging, but also for the interpolation of other types of image data based on measurements. The method, according to the disclosure, can be used wherever interpolation is carried out to increase the resolution of such image data. For the purpose of interpolation, image data is transformed here by means of a Fourier transform into the k-space, where it is interpolated before being transformed back again.

Equally preferably, the image data comprises image data generated by medical imaging devices, the resolution of which is to be increased by interpolation in the Fourier space or k-space. Such medical imaging devices comprise, in particular, devices of the following type:
X-ray imaging systems,
computed tomography systems,
ultrasound imaging systems.

Where the method is used in oversampled magnetic resonance imaging, the oversampled k-space data is preferably obtained by means of oversampling in the read-out direction or the frequency encoding direction with a predetermined oversampling factor that comprises a value greater than 1. In this variant, the removal of the image boundary areas in the image space preferably comprises the removal of image boundary areas caused by the oversampling.

In this variant, supplemented image data is generated by adding predetermined image data in a predetermined image boundary area, i.e., the supplementation of image data in the image boundary area, preferably a supplementation of the zero values, by adding a column, preferably of zero values, the longitudinal direction of which runs in the phase encoding direction. With respect to its positioning, the image boundary area corresponds to the position of one of the removed image boundary areas. The expansion of the supplemented image boundary area can now, however, comprise a single column with the thickness of just one pixel or voxel, in other words, is significantly less expanded transverse to the longitudinal direction than the image boundary area or areas that were removed beforehand. In the final formatting procedure for generating formatted interpolated image data, image boundary areas that were caused by the previously added image boundary area and are positioned in the same direction as the added image boundary area are now removed. Generally speaking, adding an image boundary area generates image boundary areas on both sides due to the subsequent transformation into the k-space and further back-transformation into the image space during interpolation; these image boundary areas are ultimately removed on both sides.

If, however, the oversampled k-space data is obtained by means of oversampling in the phase encoding direction with a predetermined oversampling factor that comprises a value greater than 1, the generation of supplemented image data by adding predetermined image data in a predetermined image boundary area, in other words, in particular, the supplementation of image data in the image boundary area, preferably of the zero values, preferably comprises an addition of a row, preferably of zero values, the longitudinal direction of which extends in the read-out direction or frequency encoding direction. With respect to its positioning, the image boundary area corresponds to the position of one of the removed image boundary areas. The expansion of the supplemented image boundary area can now, however, comprise a single row with the thickness of just one pixel or voxel, in other words, is significantly less expanded transverse to the longitudinal direction than the removed image boundary area or areas. In the final formatting procedure for generating formatted interpolated image data, the previously added image boundary area is then removed in the same direction. Generally speaking, adding an image boundary area generates image boundary areas on both sides due to the subsequent transformation into the k-space and further back-transformation into the image space during interpolation; these image boundary areas are ultimately removed on both sides.

In general terms, supplementations, preferably zero values, can be added in all three dimensions or in any dimensions in which the boundary area of an image area contains relevant image data to prevent aliasing artifacts. In addition to the above-mentioned directions, a supplementation of image data or magnetic resonance image data can also take place in the z direction of a magnetic resonance imaging system. In the context of magnetic resonance imaging, the z direction denotes the direction of the axis of rotational symmetry of a magnetic resonance imaging system.

Preferably, the reconstruction of the magnetic resonance image data comprises the use of a reconstruction method based on artificial intelligence. The scope of the input data or the training data for the training period of such a method is often considerable. Advantageously, the input data volume is reduced according to the disclosure so that the training process can be accelerated.

Here, the reconstruction method based on artificial intelligence preferably comprises a Deep Resolve method (see above), which is frequently used to reconstruct magnetic resonance image data. In the case of a Deep Resolve method in particular, the outlay required to adapt such a method to a particular type of image data can advantageously be reduced, owing to the reduced volume of training data without the occurrence of aliasing artifacts being increased.

Preferably, the generation of interpolated k-space data comprises filling boundary areas in the k-space with zero values. Filling the k-space with zero values increases the resolution of the reconstructed image data. Since the image data has already been supplemented according to the disclosure in the image space in the boundary area, preferably with zero values, it is possible to advantageously prevent the generation of aliasing artifacts that frequently occur after such an interpolation, especially where the object to be depicted is larger than the field of view that forms the basis of an imaging system.

### BRIEF DESCRIPTION OF THE DRAWINGS

The aspects of the disclosure are explained again in more detail below with reference to the attached figures based on exemplary aspects. In the figures:

FIG. 1 is a schematic overview showing a pictorial representation of a group of objects, some of which are not shown in their entirety.

FIG. 2 is a schematic overview illustrating a method for generating magnetic resonance image data from an examination object with increased resolution according to the prior art;

FIG. 3 is a schematic overview that also illustrates a method for generating magnetic resonance image data from an examination object with increased resolution according to the prior art;

FIG. 4 is a schematic overview illustrating a method for generating formatted interpolated image data, in particular, magnetic resonance image data, from an examination object according to an exemplary aspect of the disclosure;

FIG. 5 is a flow chart illustrating a method for generating formatted interpolated image data from an examination object according to an alternative exemplary aspect of the disclosure;

FIG. 6 is a flow chart illustrating sub-steps of a method for generating formatted interpolated magnetic resonance image data from an examination object according to an alternative exemplary aspect of the disclosure;

FIG. 7 is a schematic representation of an image data generation device according to an exemplary aspect of the disclosure;

FIG. 8 is a schematic representation of a magnetic resonance image data generation device according to an exemplary aspect of the disclosure; and

FIG. 9 shows a magnetic resonance imaging system according to an exemplary aspect of the disclosure.

### DETAILED DESCRIPTION

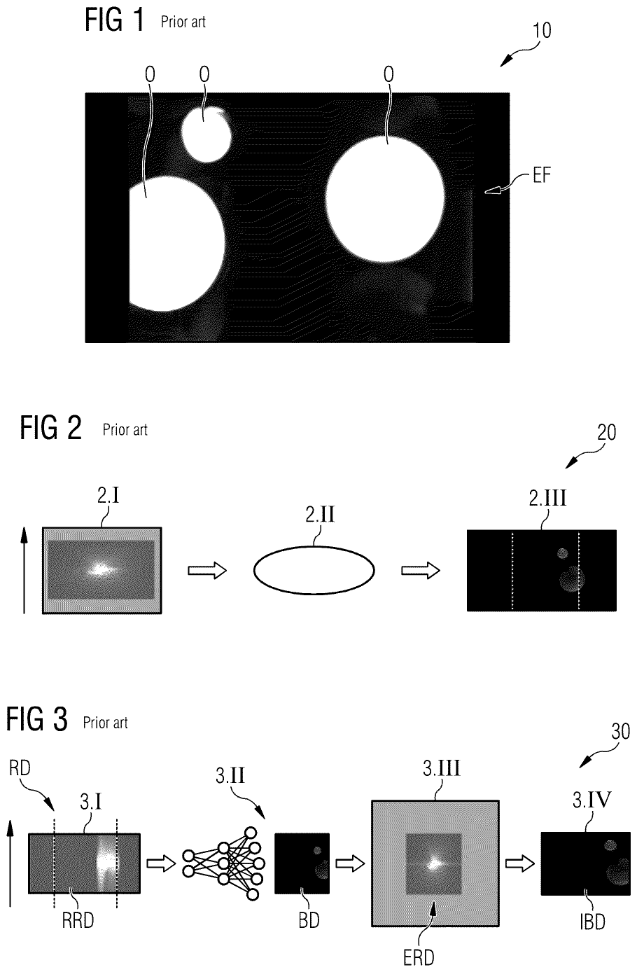

FIG. 1 contains a schematic overview 10 showing a pictorial representation of a group of objects, some of which are not shown in their entirety. The image shown in FIG. 1 results from an image interpolation in the k-space, in which the image to be interpolated was first transformed into this k-space, where it was supplemented by being filled with zero values in the boundary area. For example, the number of image points in a 2D capture is quadrupled, and the distance between image points is thus halved.

However, this method can result in aliasing artifacts, as can also be seen in FIG. 1. For the purpose of illustration, a narrow vertical line EF can be seen on the right-hand side of FIG. 1; this results from the aliasing of the left-hand image boundary on the right-hand side. Since the field of view (the field of view of the imaging system) is smaller than the dimension of the arrangement of bright light fields or objects O shown in FIG. 1, this results, in particular, in the case of MR image captures in aliasing of the left-hand boundary area on the right-hand side.

FIG. 2 contains a schematic overview 20 illustrating a method for generating magnetic resonance image data from an examination object with increased resolution according to the prior art.

FIG. 2 shows a schematic representation of the reconstruction chain for a conventional reconstruction. In step 2.I, an interpolation is first carried out in the k-space, for example, by means of zero filling. Then, in step 2.II, a conventional reconstruction of the interpolated k-space data is carried out. Finally, the reconstructed image is trimmed to the desired field of view in step 2.III. However, in the method mentioned in FIG. 2, the reconstruction takes place based on supplemented k-space data. The reconstruction, therefore, requires increased computing outlay.

FIG. 3 contains a schematic overview 30 illustrating a method for generating magnetic resonance image data from an examination object with increased resolution according to the prior art.

In step 3.I, k-space data RD generated by oversampling is transformed into the image space by means of a Fourier transform. In the image space, image boundary areas that are to be assigned to the oversampling are cut away, and the reduced image data RBD generated in this way is then transformed back into the k-space by means of a Fourier transform, resulting in reduced k-space data RRD being generated. Subsequently (see step 3.II), the actual image reconstruction (for example, using GRAPPA, SENSE, DRB, etc.) can be carried out based on the reduced k-space data RRD.

In step 3.II, an “advanced” reconstruction of image data BD is carried out based on the reduced k-space data RRD. In the exemplary aspect illustrated in FIG. 3, the “advanced” reconstruction is based on a reconstruction method in which artificial intelligence is used to reconstruct image data BD. As already mentioned, a “conventional” reconstruction can alternatively also be used. However, in the above-mentioned “advanced” reconstruction, the effect of the reduction of the data base by cutting away image boundary areas is particularly high. Since the data base for the reconstruction has been reduced, the time needed to reconstruct the image data BD is also reduced compared to a reconstruction based on non-reduced k-space data RD.

In step 3.III, the image data is then back-transformed into the k-space by means of a Fourier transform, and an interpolation is carried out in the k-space by filling the k-space with zeros, in a process called zero filling. Supplemented k-space data ERD is generated in this process.

In step 3.IV, the supplemented k-space data ERD generated in step 3.III is transformed again into the spatial domain, resulting in interpolated image data IBD.

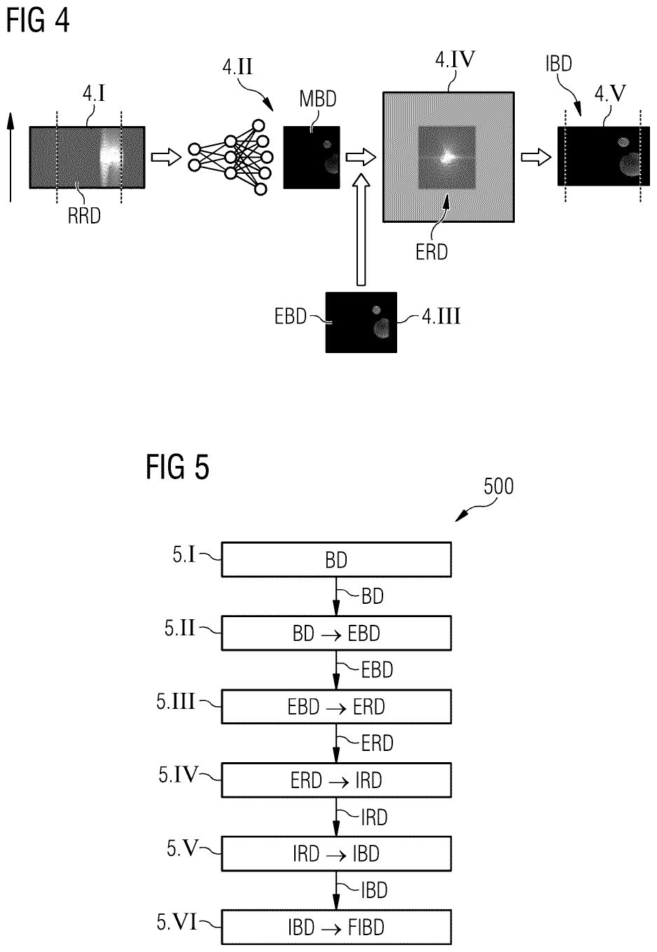

FIG. 4 shows a schematic overview 40 illustrating a method for generating formatted and interpolated magnetic resonance image data from an examination object with increased resolution according to an exemplary aspect of the disclosure. The two steps 4.I and 4.II are carried out analogously to the steps 3.I and 3.II shown in FIG. 3.

In step 4.I, therefore, raw data RD recorded by oversampling is transformed into the image space by means of a Fourier transform, resulting in image data BD being generated. In the image space, image boundary areas that are to be assigned to the oversampling are cut away, and the reduced image data generated in this way is then transformed back into the k-space by means of a Fourier transform, resulting in reduced k-space data RRD.

In step 4.II, an “advanced” reconstruction of magnetic resonance image data, MBD, is carried out based on the reduced k-space data, RRD. In the exemplary aspect illustrated in FIG. 3, the “advanced” reconstruction is based on a reconstruction method in which artificial intelligence is used to reconstruct magnetic resonance image data MBD. Since the data base for the reconstruction has been reduced, the time needed to reduce the magnetic resonance image data MBD is also reduced.

In step 4.III, zero values are now inserted in the spatial domain or the image space at the boundary of the magnetic resonance image data MBD, resulting in supplemented image data EBD. Here, the alignment of the boundary area corresponds to the alignment of the boundary areas cut away in step 4.1. A plurality of opposing or non-opposing boundary areas can also be supplemented if objects have not been fully depicted at different boundaries.

In step 4.IV, analogously to step 3.III, the supplemented image data EBD is back-transformed into the k-space by means of a Fourier transform, and an interpolation is carried out in the k-space by filling the k-space with zeros, in a process called zero filling. Supplemented k-space data ERD is generated in this process.

In step 4.V, the supplemented k-space data ERD is transformed back into the spatial domain, resulting in expanded and interpolated image data IBD being generated.

Furthermore, boundary areas that contain zero values as a result of the zero filling in step 4.III are cut away in step 4.V, resulting in formatted interpolated image data FIBD being generated. In a departure from the procedure shown in FIG. 3, the supplementation of zero values in step 4.III makes it possible to prevent aliasing artifacts in the formatted interpolated image data FIBD.

FIG. 5 shows a flow chart 500 illustrating a method for generating formatted interpolated image data from an examination object with increased resolution according to an alternative exemplary aspect of the disclosure.

In step 5.I, image data BD is generated from an image capture area. The image data BD may comprise photographic image data or magnetic resonance image data MBD, for example.

In step 5.II, supplemented image data EBD is generated by supplementing the image data BD with zero values in an image boundary area in which an object borders on the image boundary. This measure is critical for avoiding aliasing artifacts during the subsequent interpolation.

In step 5.III, supplemented k-space data ERD is generated by transforming the supplemented image data EBD into the k-space or Fourier space by means of a Fourier transform. The transformation into the Fourier space is carried out because the actual interpolation is performed to increase the image resolution in the Fourier space.

In step 5.IV, interpolated k-space data IRD is generated by interpolating the supplemented k-space data ERD in the k-space.

Interpolated image data IBD is then generated in step 5.V by means of an image reconstruction based on the interpolated k-space data IRD.

In step 5.VI, formatted interpolated image data FIBD is generated by removing boundary areas of the interpolated image data IBD.

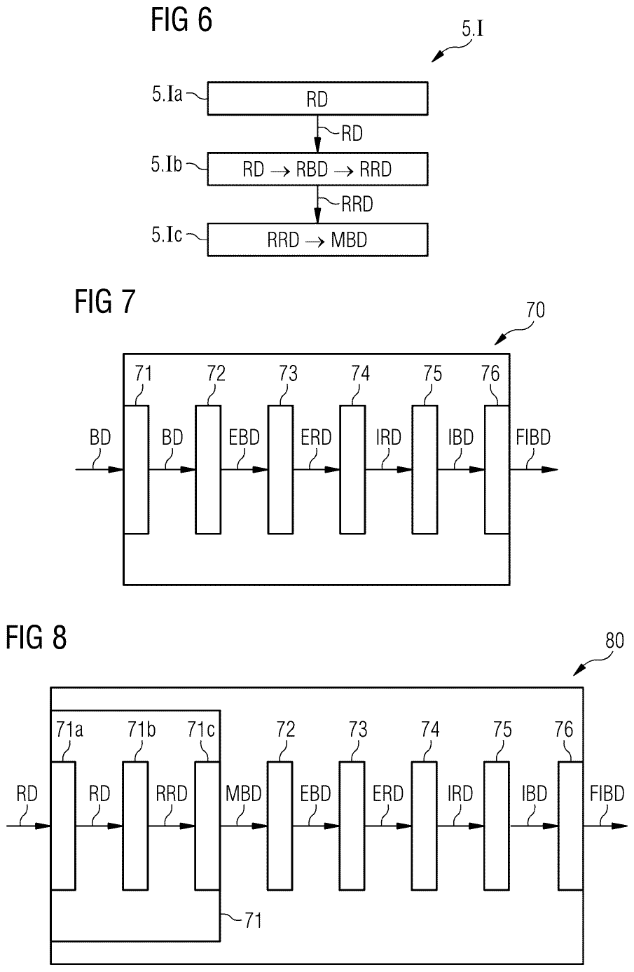

FIG. 6 shows a flow chart illustrating the first steps of a method for generating formatted interpolated image data from an examination object with increased resolution according to an alternative exemplary aspect of the disclosure, which are used specifically when applying the method according to the disclosure to magnetic resonance image data. The steps shown in FIG. 6 are comprised by step 5.I shown in FIG. 5.

In the exemplary aspect illustrated in FIG. 6, in step 5.Ia oversampled raw data RD from an examination object is captured by a scanner unit of a magnetic resonance imaging system.

In step 5.Ib, the raw data RD is transformed from the k-space into the image space. In the image space, image boundary areas resulting from the oversampling are cut away, and the reduced image data RBD generated in this way is then transformed back into the k-space by means of a Fourier transform, resulting in reduced k-space data RRD. In this way, the data volume of the k-space data that later serves as the basis for an image reconstruction is reduced, resulting in reduced k-space data RRD being generated.

In step 5.Ic, magnetic resonance image data MBD is reconstructed based on the reduced k-space data RRD. This magnetic resonance image data MBD is then further processed as image data BD using the method illustrated in FIG. 5.

In FIG. 7 a schematic representation of an image data generation device 70 according to an exemplary aspect of the disclosure is illustrated.

The image data generation device 70 comprises an image capture unit 71 for capturing image data BD from an image capture area.

The image data generation device 70 comprises a supplementation unit 72 for generating supplemented image data EBD by supplementing the image data BD with zero values in an image boundary area. The zero values are supplemented to prevent aliasing artifacts in the opposing image boundary area during the subsequent interpolation.

Another element of the image data generation device 70 is a transformation unit 73 for generating supplemented k-space data ERD by transforming the supplemented image data EBD into the k-space.

The image data generation device 70, according to the disclosure, also comprises an interpolation unit 74 for generating interpolated k-space data IRD by interpolating the supplemented k-space data ERD.

Furthermore, the image data generation device 70 according to the disclosure has an image generation unit 75 for generating interpolated image data IBD by means of an image reconstruction based on the interpolated k-space data IRD.

A further element of the image data generation device 70 according to the disclosure is a formatting unit 76 for generating formatted interpolated image data FIBD by removing boundary areas of the interpolated image data IBD.

FIG. 8 shows a magnetic resonance image data generation device 80 according to an exemplary aspect of the disclosure.

The magnetic resonance image data generation device 80 is an aspect of the image data generation device 70 already illustrated in FIG. 7 and comprises a special image capture unit 71, which has the following sub-units 71a, 71b, 71c:
The image capture unit 71 comprises an input interface 71a for receiving oversampled k-space data RD from an examination area ROI of an examination object O, which is sampled in the context of magnetic resonance imaging.

Another element of the image capture unit 71 is a reduction unit 71b for generating reduced k-space data RRD by removing an area assigned to the oversampling in the image space.

Finally, the image capture unit 71 also comprises a reconstruction unit 71c for reconstructing magnetic resonance image data MBD based on the reduced k-space data RRD.

The other components 72, 73, . . . , 76 shown in FIG. 8 correspond to the components 72, 73, . . . , 76 already illustrated in FIG. 7 of the image data generation device 70 illustrated in FIG. 7.

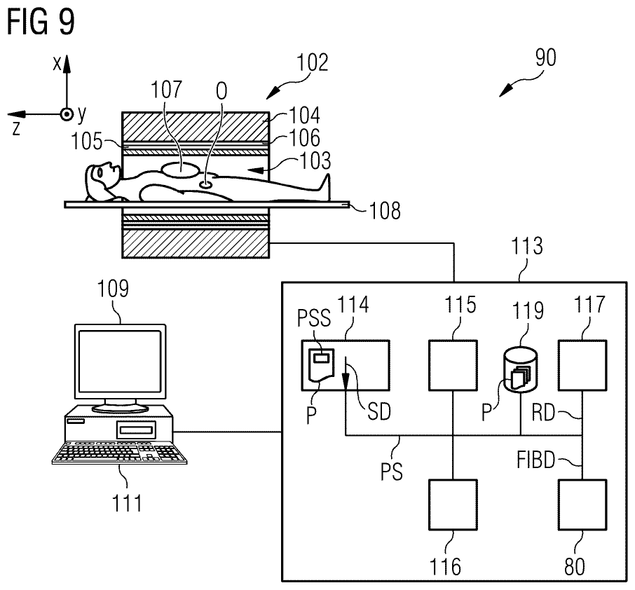

FIG. 9 shows a magnetic resonance imaging system 90, also referred to as an MR system, according to an exemplary aspect of the disclosure, which comprises a magnetic resonance image data generation device 80 according to an exemplary aspect of the disclosure, as illustrated in FIG. 8.

The magnetic resonance imaging system 90 comprises the actual magnetic resonance scanner or the magnetic resonance scanner unit 102 with an examination chamber 103 or patient tunnel, into which a patient O, or in this case a patient or test subject whose body contains a specific organ to be examined, for example, can be transported on a couch 108.

The magnetic resonance scanner 102 is equipped in the usual manner with a basic field magnet system 104, a gradient system 106, as well as an HF transmitter antenna system 105 and an HF receiver antenna system 107. In the exemplary aspect shown, the HF transmitter antenna system 105 is a whole-body coil permanently installed in the magnetic resonance scanner 102, whereas the HF receiver antenna system 107 consists of local coils to be arranged on the patient or test subject (symbolized by a single local coil only in FIG. 9). In principle, however, the whole-body coil 105 can also be used as HF receiver antenna system and the local coils 107 as HF transmitter antenna system, as long as these coils are respectively capable of being switched to different operating modes.

The MR system 90 also has a central control device 113, which is used to control the MR system 90. This central control device 113 comprises a sequence control unit 114 for pulse sequence control. This is used to control the chronological sequence of high-frequency pulses (HF pulses) and of gradient pulses as a function of a selected imaging sequence PS according to a pulse sequence scheme PSS. Such an imaging sequence PS or the pulse sequence scheme PSS that forms the basis of the imaging sequence PS can be specified within a measurement protocol or control protocol P, for example. Usually, various control protocols P for different measurements are stored in a memory 119 and can be selected by an operator (and modified if necessary) and are then used to perform the measurement.

To output the individual HF pulses, the central control device 113 has a high frequency transmitter device 115 that generates the HF pulses, amplifies them, and feeds them via a suitable interface (not shown in detail) into the HF transmitter antenna system 105. To control the gradient coils of the gradient system 106, the control device 113 has a gradient system interface 116. The sequence control unit 114 communicates in a suitable manner, e.g., by transmitting sequence control data SD, with the high frequency transmitter device 115 and the gradient system interface 116 for transmitting the pulse sequence PS. The control device 113 also has a high frequency receiver device 117 (which also communicates with the sequence control unit 114 in a suitable manner) to acquire magnetic resonance signals received from the HF transmitter antenna system 107 in a coordinated manner.

The central control device 113 also comprises a magnetic resonance image data generation device 80 according to the disclosure, which has the setup illustrated in detail in FIG. 8.

The magnetic resonance image data generation device 80 is configured to accept the acquired data after demodulation and digitization as raw data or k-space data RD and to reconstruct formatted interpolated magnetic resonance image data FIBD from this. This magnetic resonance image data FIBD can then be saved in a memory 119, for example.

The central control device 113 can be operated via a terminal with an input unit 111 and a display unit 109, via which the entire MR system 90 can thus also be operated by an operator. MR image data FIBD can also be displayed on the display unit 109, and the input unit 111, if appropriate in combination with the display unit 109, can be used to plan and start measurements and, in particular, to select suitable control protocols with suitable measurement sequences as explained above, and to modify them if applicable.

The MR system 90 according to the disclosure, and, in particular, the control device 113, can furthermore have a plurality of additional components that are not shown here in detail but are usually present on such devices, such as a network interface to connect the entire system to a network and to enable the exchange of raw data RD and/or image data or parameter cards, as well as additional data such as patient-related data or control protocols.

The way in which suitable raw data RD can be acquired by emitting HF pulses and generating gradient fields, and how MR image data can be reconstructed from this, is known in principle to the person skilled in the art and will not be explained in detail here.

It is clear from the above that the disclosure provides effective possibilities for improving a method for generating magnetic resonance image data with respect to the amount of time needed or the image artifacts that occur.

It should be noted that the characteristics of all exemplary aspects or of developments disclosed in figures can be used in any combination.

Finally, reference is also made once more to the fact that the detailed method and setups described above are exemplary aspects and that the basic principle may also be varied in wide fields by the person skilled in the art, without deviating from the field of the disclosure, insofar as this is specified by the claims. For the sake of completeness, it is also stated that the use of the indefinite article “a” does not exclude the features concerned from also being present multiple times. Similarly, the term “unit” does not exclude this comprising multiple components that may also be spatially distributed. Gender-neutral language is used throughout this text.

1. A method for generating formatted interpolated image data, comprising:
capturing image data from an image capture area with a predetermined image format that depicts the image capture area;
generating supplemented image data by adding predetermined image data in a predetermined image boundary area that lies outside the predetermined image format and borders on the predetermined image format;
transforming the supplemented image data into k-space to generate supplemented k-space data;
generating interpolated k-space data by interpolating the supplemented k-space data, by which non-measured k-space data is generated based on the supplemented k-space data;
reconstructing interpolated image data based on the interpolated k-space data, the interpolated image data comprising image boundary areas that lie outside the predetermined image format; and
generating formatted interpolated image data by removing the image boundary areas that lie outside the predetermined image format in the interpolated image data.

2. The method of claim 1, wherein the removed image boundary areas comprise opposing image boundary areas that are arranged in a same direction as the predetermined image boundary area.

3. The method of claim 1, wherein the generation of supplemented image data is carried out by:
supplementing the predetermined image boundary area with constant values;
supplementing the predetermined image boundary area with the boundary value;
supplementing the predetermined image boundary area with zero values; or
supplementing the predetermined image boundary area with image data based on a reflection from an opposing image boundary area.

4. The method of claim 1, wherein the image data comprises image data of an optical image capture unit.

5. The method of claim 1, wherein the image data comprises magnetic resonance image data or is obtained based on magnetic resonance image data, and the step of capturing image data from an image capture area comprises:
receiving k-space data from an examination area of an examination object; and
reconstructing the magnetic resonance image data based on the k-space data.

6. The method of claim 5, wherein the image data is captured by removing predetermined image boundary areas of the magnetic resonance image data that lie outside the predetermined image format and border on the predetermined image format.

7. The method of claim 5, wherein the step of capturing image data from an image capture area comprises:
generating reduced image data by transforming the received k-space data into image space and removing image boundary areas in the image space that lie outside the predetermined image format and border on the predetermined image format;
back-transforming the reduced image data into the k-space, reduced k-space data being generated; and
reconstructing the magnetic resonance image data based on the reduced k-space data.

8. The method of claim 6, wherein the received k-space data comprises oversampled k-space data and the oversampled k-space data is acquired using oversampling in a read-out direction and/or phase encoding direction with a predetermined oversampling factor that comprises a value greater than 1, and the removal of the image boundary areas comprises the removal of image boundary areas caused by the oversampling.

9. The method of claim 8, wherein the generating supplemented image data by adding predetermined image data in a predetermined image boundary area comprises:
if oversampling in the read-out direction, adding a column that runs in the phase encoding direction; and
if oversampling in the phase encoding direction, adding a row that runs in the read-out direction.

10. The method of claim 5, wherein the reconstructing the magnetic resonance image data comprises applying a reconstruction method based on artificial intelligence.

11. An image data generation device, comprising:
an image capture unit configured to capture image data from an image capture area with a predetermined image format that depicts the image capture area;
a supplementation unit configured to generate supplemented image data by adding predetermined image data in a predetermined image boundary area that lies outside the predetermined image format and borders on the predetermined image format;
a transformation unit configured to transform the supplemented image data into k-space to generate supplemented k-space data;
an interpolation unit configured to generate interpolated k-space data by interpolating the supplemented k-space data, using which non-measured k-space data is generated based on the supplemented k-space data;
an image generation unit configured to generate interpolated image data using an image reconstruction based on the interpolated k-space data, the interpolated image data comprising image boundary areas that lie outside the predetermined image format; and
a formatting unit configured to generate formatted interpolated image data by removing the image boundary areas that lie outside the predetermined image format in the interpolated image data.

12. The image data generation device of claim 11, wherein the image data comprises magnetic resonance image data and the image capture unit comprises:
an input interface configured to receive k-space data from an examination area of an examination object;
a reduction unit configured to generate reduced k-space data by transforming the k-space data into image space and remove image boundary areas of the image data that lie outside the predetermined image format and border on the predetermined image format, such that reduced image data is generated, and to back-transform the reduced image data into the k-space, such that reduced k-space data is generated; and
a reconstruction unit configured to reconstruct magnetic resonance image data based on the reduced k-space data.

13. A magnetic resonance imaging system, comprising:
a scanner unit;
a central control device configured to actuate the scanner unit; and
the image data generation device of claim 12 configured to process k-space data of the scanner unit.

14. A non-transitory computer-readable storage medium comprising commands which, when executed by a computer, cause the computer to carry out the steps of the method of claim 1.
